(19) United States
(12) Patent Application Publication
(10) Pub. No.: US 2025/0218885 A1
(43) Pub. Date: Jul. 3, 2025

(54) PATTERNED MOLD UNDERFILL (MUF) FILMS FOR DEEP TRENCH FILLING

(71) Applicant: Intel Corporation, Santa Clara, CA (US)

(72) Inventors: Hong Seung YEON, Chandler, AZ (US); Zhixin XIE, Chandler, AZ (US); Anup PANINDRE, Chandler, AZ (US); Yosuke KANAOKA, Chandler, AZ (US); Jung Kyu HAN, Chandler, AZ (US); Gang DUAN, Chandler, AZ (US); Srinivas Venkata Ramanuja PIETAMBARAM, Chandler, AZ (US)

(21) Appl. No.: 18/398,725

(22) Filed: Dec. 28, 2023

(51) Int. Cl. H01L 23/31; H01L 21/02; H01L 25/16

(52) U.S. Cl. CPC H01L 23/315; H01L 21/02422; H01L 23/3121; H01L 25/16

(57) ABSTRACT

Embodiments disclosed herein include components that are embedded in the core of a package substrate. In an embodiment, such an apparatus comprises a substrate with a cavity through a thickness of the substrate. In an embodiment, a component is in the cavity, and a first layer is in the cavity. In an embodiment the first layer is a dielectric material. In an embodiment, a second layer is in the cavity, and the second layer is a dielectric material that is a different material than the second layer.

### BACKGROUND

In electronics packaging, chip scaling technology can lead to rising average and transient current. This increases demands on power delivery, especially for high performance applications. In order to improve power delivery, passive electrical components (e.g., capacitors, inductors, resistors, etc.) may be integrated into the package substrate that underlies the one or more chips. Typically, these components are embedded into the core of the package substrate.

However, the thickness of the components is often different than the thickness of the core. The core may have a large thickness in order to provide necessary mechanical support, planarity, and the like. For example, cores may have thicknesses of approximately 1 mm or greater. In contrast, the thickness of components is often smaller. In the case of capacitor components, deep trench capacitors (DTCs) are fabricated on silicon wafers. The thickness of the wafer is typically smaller than that of the core.

After placing the passive component in a cavity through the core, the remainder of the cavity is encapsulated with a molding material or the like. However, due to the large amount of empty space in the cavity, the molding material will typically form a dent or depression across the cavity. This leads to a non-planar surface, which can generate issues with planarity in subsequent assembly operations.

### BRIEF DESCRIPTION OF THE DRAWINGS

FIG. 1A is a cross-sectional illustration of a core with a cavity and a component placed in the cavity, in accordance with an embodiment.

FIG. 1B is a cross-sectional illustration of the core after a film is disposed over the core and into the cavity, and a depression is provided over the cavity, in accordance with an embodiment.

FIG. 1C is a cross-sectional illustration of the core after the temporary carrier is removed, in accordance with an embodiment.

FIG. 2A is a cross-sectional illustration of a core with a cavity and a component placed in the cavity, in accordance with an embodiment.

FIG. 2B is a cross-sectional illustration of the core after a film with a first layer and a second layer is disposed over the core and into the cavity, in accordance with an embodiment.

FIG. 2C is a cross-sectional illustration of the core after the temporary carrier is removed, in accordance with an embodiment.

FIG. 2D is a process flow diagram of a process for embedding a component in a cavity and filling with a multi-layer film, in accordance with an embodiment.

FIG. 3A is a cross-sectional illustration of a core with a cavity and a component placed in the cavity, in accordance with an embodiment.

FIG. 3B is a cross-sectional illustration of the core after a film is disposed over the core and into the cavity, and a depression is provided over the cavity, in accordance with an embodiment.

FIG. 3C is a cross-sectional illustration of the core after a second film with a second layer and a third layer is provided above the core, in accordance with an embodiment.

FIG. 3D is a cross-sectional illustration of the core after the second layer fills the depression, in accordance with an embodiment.

FIG. 3E is a cross-sectional illustration of the core after the temporary carrier is removed, in accordance with an embodiment.

FIG. 3F is a process flow diagram of a process for embedding a component in a cavity and filling with a multi-layer film, in accordance with an embodiment.

FIG. 4A is a cross-sectional illustration of a core with a component in a cavity and a film with a fill layer over the core, and the core and the fill layer have alignment features, in accordance with an embodiment.

FIG. 4B is a cross-sectional illustration of the core with the film coupled to the core with the alignment features interlocking with each other, in accordance with an embodiment.

FIG. 5A is a cross-sectional illustration of a core with a component in a cavity and a film with a fill layer over the core, and the core and the fill layer have alignment features, in accordance with an embodiment.

FIG. 5B is a cross-sectional illustration of the core with the film coupled to the core with the alignment features interlocking with each other, in accordance with an embodiment.

FIGS. 6A-6D are cross-sectional illustrations depicting different alignment features, in accordance with various embodiments.

FIG. 6E is a plan view illustration of a panel showing locations for the alignment features, in accordance with an embodiment.

FIG. 7 is a cross-sectional illustration of an apparatus with a core and a film that are aligned with an alignment frame, in accordance with an embodiment.

FIG. 8 is a cross-sectional illustration of an electronic system with a package substrate that includes a component embedded in a cavity that is filled by a first layer and a second layer, in accordance with an embodiment.

FIG. 9 is a schematic of a computing device built in accordance with an embodiment.

### EMBODIMENTS OF THE PRESENT DISCLOSURE

Described herein are electronic systems, and more particularly, architectures with electronic packages that include cores with embedded components that are surrounded by a film with a first layer and a second layer, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, components may be embedded within electronic package substrates. More particularly, electrically passive components, such as capacitors, inductors, resistors, and the like may be embedded within a core of the package substrate. These embedded components can be used for any suitable purpose. One such purpose is to improve power delivery performance.

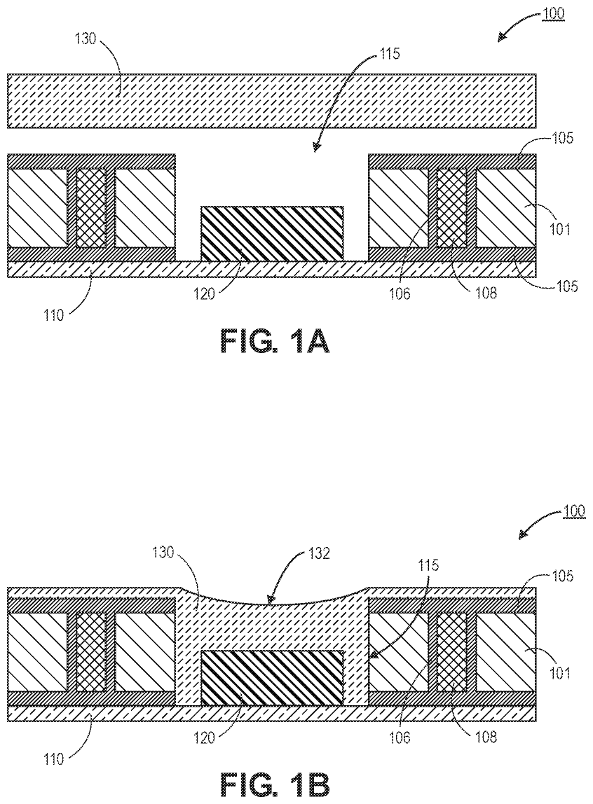

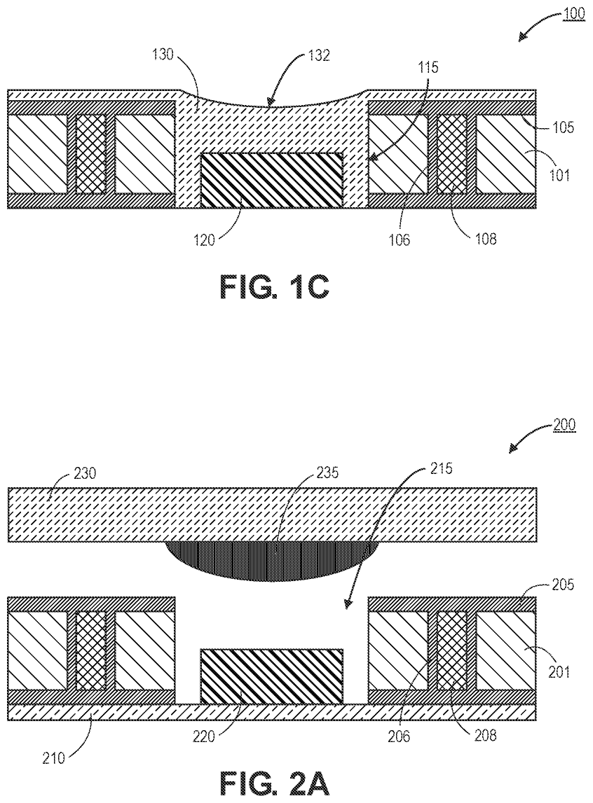

Often, the thickness of the embedded component is different than the thickness of the core. When a dielectric fill material (e.g., a mold underfill (MUF)) is provided over the component in a cavity, a dent or depression may be provided across the cavity. This can lead to problems in subsequent processing operations since a non-planar surface is provided. An example of such situation is shown in FIGS. 1A-1C.

Referring now to FIG. 1A, a cross-sectional illustration of a portion of a package substrate 100 is shown, in accordance with an embodiment. In an embodiment, the package substrate 100 may comprise a core 101. The core 101 may be a glass core or an organic core. In some instances, an electrically conductive cladding 105 may be provided over the top and/or bottom of the core 101. For example, the cladding 105 may comprise copper or the like. In an embodiment, one or more vias 106 may pass through a thickness of the core 101. In the illustrated embodiment, the vias 106 are hollow shells that are filled with an insulating plug 108. Though, in other embodiments the vias 106 are fully filled.

In an embodiment, a cavity 115 is formed into or through the core 101. A component 120 is placed into the cavity 115. In the case of the cavity 115 going entirely through the core 101, a temporary carrier 110 or tape is provided across the bottom of the core 101 to support the component 120. As shown, the thickness of the component 120 is different than the thickness of the core 101. In an embodiment, a layer 130 or the like is positioned over the core 101. The layer 130 may be a molding material, such as a MUF.

Referring now to FIG. 1B, a cross-sectional illustration of a portion of the package substrate 100 at a subsequent stage of manufacturing is shown, in accordance with an embodiment. In an embodiment, the layer 130 has been applied to the core 101. For example, a lamination process or the like may be used in order to deposit the layer 130 onto the core 101. As shown, the layer 130 at least partially fills the cavity 115. The layer 130 may be considered as embedding the component 120. That is, the layer 130 may cover sidewalls and a top surface of the component 120. The layer 130 may also be provided over the top surface of the core 101. When a cladding 105 is present, the layer 130 may be separated from the core 101 by the cladding 105.

In an embodiment, the layer 130 may not fully fill the cavity 115. As shown, a depression 132 may be provided in the layer 130 across the width of the cavity 115. The depression 132 may be formed since there is a larger volume to fill below the depression. Flowability of the layer 130 may also contribute to the generation of the depression 132.

Referring now to FIG. 1C, a cross-sectional illustration of a portion of the package substrate 100 at a subsequent processing operation is shown, in accordance with an embodiment. In FIG. 1C the underlying temporary carrier 110 has been removed. The temporary carrier 110 may be removed with a peeling process, an etching process, a delamination, or the like. Removal of the temporary carrier 110 exposes a bottom surface of the component 120. While not shown, the bottom surface of the component 120 may comprise pads or the like. These pads can then be used to electrically couple the component 120 to other features (e.g., dies, etc.) through routing in subsequently formed buildup layers that are to be built over and under the core 101.

As can be appreciated, the formation of a depression 132 in the layer 130 can result in negative manufacturing outcomes in subsequent package assembly operations. For example, the depression 132 causes the surface to be non-planar. This is particularly problematic since high planarity is necessary in order to accurately form pads, vias, traces, and the like in overlying and/or underlying buildup layers. The buildup layers are typically formed with a lamination process. As such, the depression 132 will persist into each subsequent layer. As such, yield is negatively impacted since interconnects may be formed incorrectly.

Accordingly, embodiments disclosed herein include layering structures that prevent or mitigate the formation of depressions in the presence of cavities filled with components. In one instance, a film is applied to the core, and the film has a first layer and a second layer. The first layer is aligned over the cavity, and the second layer expands across the entire core. The first layer may be a different material than the second layer. For example, the first layer may have a higher flowability in some instances. When applied to the core, the first layer at least partially embeds the component, and the second layer fills the remainder of the cavity and is provided over the core. The addition of the first layer prevents the formation of a depression.

In another embodiment, a first film with a first layer is provided over the core and into the cavity. This is similar to the embodiment shown in FIGS. 1A-1C. However, a second film is then applied over the first film. The second film has a second layer and a third layer. The second layer is aligned with the depression in the first layer, and the second layer fills the depression. Accordingly, there is an interface between the first layer and the second layer that is non-linear or curved. The combination of the first layer and the second layer provides a flat surface that supports the third layer.

As can be appreciated, embodiments disclosed herein may benefit from accurate alignment of the various layers. Particularly, accurate alignment of the layer localized over the cavity allows for optimal benefits. This can be accomplished through several different alignment configurations. In one instance, the films may include alignment features (e.g., interlocking protrusions/cavities). In another instance, the core and film may be placed in frames that include alignment features.

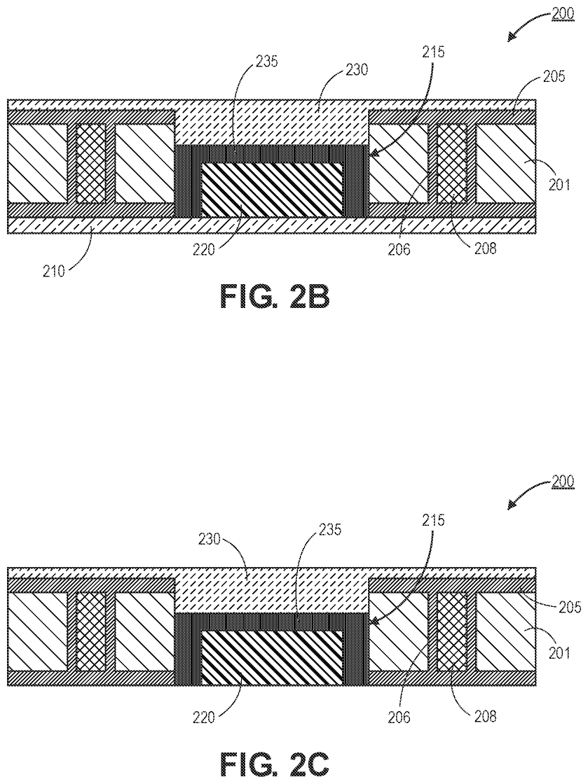

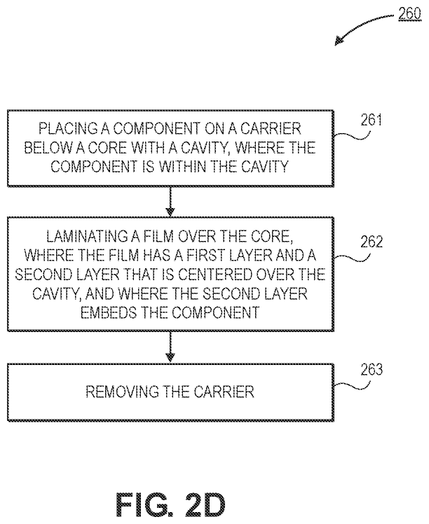

Referring now to FIGS. 2A-2C, cross-sectional illustrations depicting a process for embedding a component with a film that includes a first layer and a second layer is shown, in accordance with an embodiment.

Referring now to FIG. 2A, a cross-sectional illustration of a portion of a package substrate 200 is shown, in accordance with an embodiment. The package substrate 200 may comprise a core 201. In an embodiment, the core 201 may comprise an organic core or glass core. In the case of an organic core, the core 201 may be an organic dielectric material with fiber reinforcement. For example, glass fibers or the like may be used in some embodiments. In the case of a core 201 that comprises glass, the core 201 may be substantially all glass. The core 201 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, core 201 may be distinguished from, for example, the “prepreg” or “RF4” core of a Printed Circuit Board (PCB) substrate which typically comprises glass fibers embedded in a resinous organic material, such as an epoxy.

The core 201 may have any suitable dimensions. In a particular embodiment, the core 201 may have a thickness that is approximately 50 μm or greater. For example, the thickness of the core 201 may be between approximately 50 μm and approximately 1.4 mm. Though, smaller or larger thicknesses may also be used. The core 201 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the core 201 (from an overhead plan view) may be between approximately 10 mm×10 mm and approximately 250 mm×250 mm. In an embodiment, the core 201 may have a first side that is perpendicular or orthogonal to a second side. In a more general embodiment, the core 201 may comprise a rectangular prism volume with sections (e.g., vias) removed and filled with other materials (e.g., metal, etc.).

The core 201 may comprise a single monolithic layer of glass. In other embodiments, the core 201 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the core 201 may each have a thickness less than approximately 50 μm. For example, discrete layers of glass in the core 201 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The core 201 may be any suitable glass formulation that has the necessary mechanical robustness and compatibility with semiconductor packaging manufacturing and assembly processes. For example, the core 201 may comprise aluminosilicate glass, borosilicate glass, alumino-borosilicate glass, silica, fused silica, or the like. In some embodiments, the core 201 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the core 201 may comprise silicon and oxygen, as well as any one or more of aluminum, boron, magnesium, calcium, barium, tin, sodium, potassium, strontium, phosphorus, zirconium, lithium, titanium, or zinc. In an embodiment, the core 201 may comprise at least 23 percent silicon (by weight) and at least 26 percent oxygen (by weight). In some embodiments, the core 201 may further comprise at least 5 percent aluminum (by weight).

In an embodiment, the core 201 may comprise one or more vias 206 that pass through a thickness of the core 201. The vias 206 may be hollow cylinders or shells comprising electrically conductive material (e.g., copper) with an insulating plug 208, or the like. In other embodiments, the vias 206 may be fully filled. The profile of the vias 206 may include vertical sidewalls, sloped sidewalls, hourglass shaped cross-sections, or any other suitable profile. A cladding 205 may also be provided over and/or under the core 201. The cladding 205 may comprise an electrically conductive material, such as copper or the like.

In an embodiment, a cavity 215 may be provided into a surface of the core 201. The cavity 215 may be provided entirely through a thickness of the core 201, or the cavity 215 may pass partially through a thickness of the core 201. In some instances, the cavity 215 may be referred to as a hole. In an embodiment, the sidewalls of the cavity 215 may have any profile. In FIG. 2A, the sidewalls are substantially vertical (i.e., substantially orthogonal to the top surface of the core 201). In other embodiments, the sidewalls may be tapered, curved, or any other suitable profile. A temporary carrier 210 may be provided on a bottom of the core 201. The temporary carrier 210 may span across the cavity 215 in order to provide a support surface for placing a component 220. The temporary carrier 210 may comprise a substrate (e.g., silicon, glass, metal, etc.), a tape, or the like.

In an embodiment, a component 220 is positioned within the cavity 215. The component 220 may have a thickness that is smaller than a thickness of the core 201. The component 220 is supported by the temporary carrier 210 at a bottom of the cavity 215. In the illustrated embodiment, a single component 220 is provided in the cavity 215. In other embodiments, two or more components 220 may be positioned within a single cavity 215.

The component 220 may be any type of component. In some embodiments, the component 220 is an electrically passive component. Passive components may include electrical features, such as one or more of a capacitor, an inductor, a resistor, or the like. In one embodiment, the component 220 comprises a deep trench capacitor (DTC). A DTC may include capacitors that are formed in deep trenches into a silicon substrate or the like. The electrical circuitry and routing (e.g., pads, traces, vias, electrodes, etc.) are omitted from the illustration of the component 220 for simplicity. In some embodiments, the pads to connect the component 220 to external routing may be provided on the bottom of the component 220 (as viewed in FIG. 2A).

In an embodiment, a film is shown above the core 201. The film may comprise a first layer 230 and a second layer 235. The first layer 230 may be a different material than the second layer 235. In an embodiment, the second layer 235 may have a higher flowability than the first layer 230. That is, the first layer 230 may have a first viscosity, and the second layer 235 may have a second viscosity that is lower than the first layer 230. As such, the application of force to the film (e.g., during a lamination process) allows for the second layer 235 to deform and “flow” better than the first layer 230. This allows for improved filling of the cavity 215 and embedding of the component 220, as will be described in greater detail below. The first layer 230 and the second layer 235 may comprise any suitable material or class of materials. For example, the first layer 230 and the second layer 235 may comprise a polymer, an epoxy, an epoxy mold compound, a MUF, an organic dielectric, a composite material, or the like. In some embodiments, the first layer 230 and/or the second layer 235 may also comprise micro or nano-sized inorganic particulate fillers, fibers, or a mixture of fibers and particulate fillers.

In an embodiment, the first layer 230 has a width that substantially matches the width of the core 201, and the second layer 235 has a smaller width. The second layer 235 may be aligned with the cavity 215. For example, a centerline of the second layer 235 may be substantially aligned with the centerline of the cavity 215. As used herein, “substantially aligned” may refer to two lines that are within 50 μm of being aligned with each other. In the illustrated embodiment, the second layer 235 is semi-elliptical in shape. Though, other profiles may also be provided for the second layer 235. The width of the second layer 235 may be similar to the width of the cavity 215. Though, the second layer 235 may have a width that is larger or smaller than the width of the cavity 215 as well.

Referring now to FIG. 2B, a cross-sectional illustration of a portion of the package substrate 200 at a subsequent stage of assembly is shown, in accordance with an embodiment. As shown, the film has been applied to the core 201. For example, the film may be laminated, molded, pressed, or the like onto the core 201. The application process results in the second layer 235 being disposed at a bottom region of the cavity 215. In the illustrated embodiment, the second layer 235 embeds the component 220. That is, the second layer 235 contacts sidewalls and a top surface of the component 220. In other embodiments, the second layer 235 may only cover portions of the sidewalls of the component 220.

In an embodiment, the first layer 230 may fill the remainder of the cavity 215. In some instances, the first layer 230 and the second layer 235 may have a substantially linear interface with each other. Though, a non-linear interface is also possible. In addition to filling the remainder of the cavity 215, the first layer 230 may also cover a top surface of the core 201. In embodiments with a cladding 205, the first layer 230 may be separated from the core 201 by the cladding 205.

As shown, the top surface of the first layer 230 is substantially linear and substantially parallel to the top surface of the core 201. This provides a good foundation to build up additional routing and buildup layers. The absence of a depression or other deformation above the cavity 215 can be attributable to the addition of the second layer 235. The enhanced flowability allows for improved filling of the cavity 215 and embedding of the component 220. Additionally, the additional volume of the second layer 235 renders the cavity 215 easier to fill.

Referring now to FIG. 2C, a cross-sectional illustration of a portion of the package substrate 200 at an additional stage of manufacturing is shown, in accordance with an embodiment. FIG. 2C shows the removal of the temporary carrier 210. The temporary carrier 210 may be removed with a peeling process, an etching process, a delamination, or the like. Removal of the temporary carrier 210 exposes a portion of the second layer 235. Accordingly, with respect to the film, one side of the core 201 (e.g., the top side) includes exposed portions of only the first layer 230, and the other side of the core 201 (e.g., the bottom side) includes exposed portions of only the second layer 235.

Referring now to FIG. 2D, a process flow diagram of a process 260 for embedding a component in a cavity within a core is shown, in accordance with an embodiment. In an embodiment, the process 260 may begin with operation 261, which comprises placing a component on a carrier below a core within a cavity. In an embodiment, the component is within the cavity. The operation 261 may be similar to the structure and process described and illustrated with respect to FIG. 2A.

In an embodiment, the process 260 may continue with operation 262, which comprises laminating a film over the core. In an embodiment, the film has a first layer and a second layer that is centered over the cavity. In an embodiment, the second layer embeds the component. The operation 262 may be similar to the structure and process described and illustrated with respect to FIG. 2B.

In an embodiment, the process 260 may continue with operation 263, which comprises removing the carrier. The operation 263 may be similar to the structure and process described and illustrated with respect to FIG. 2C.

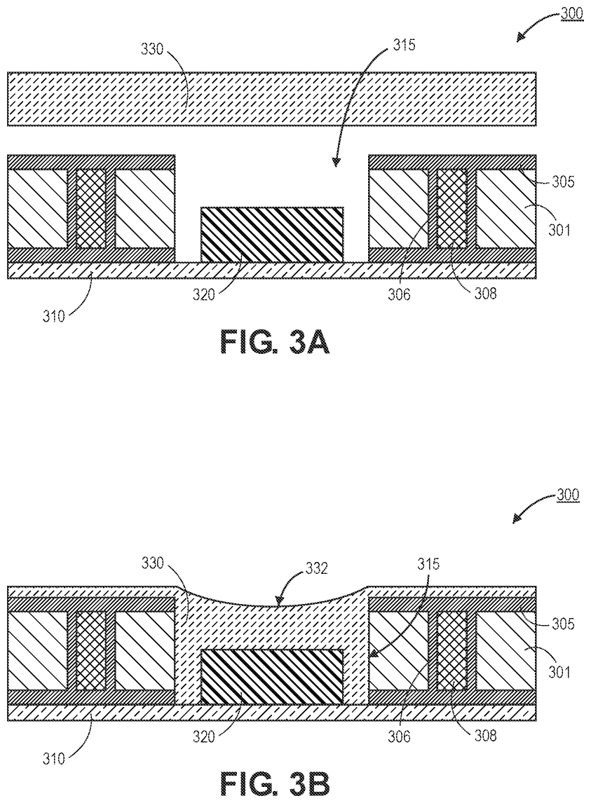

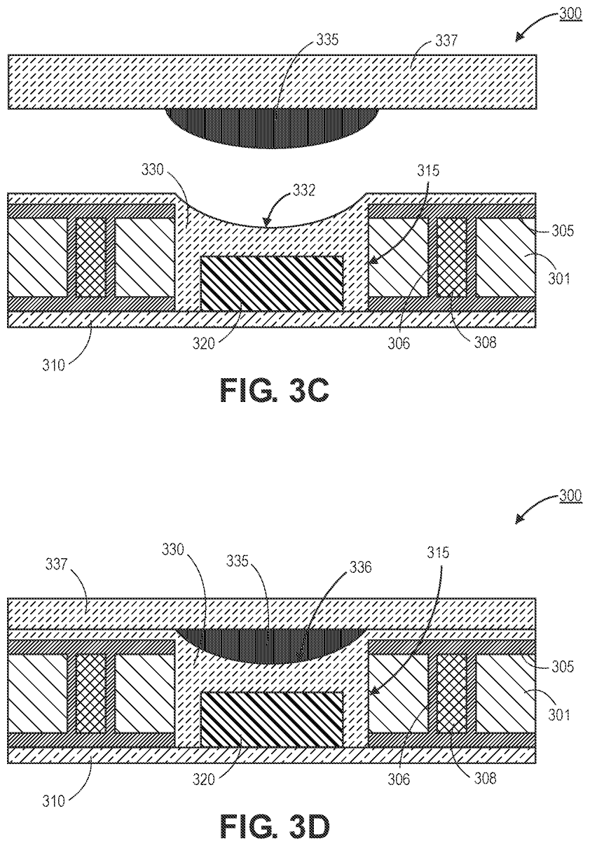

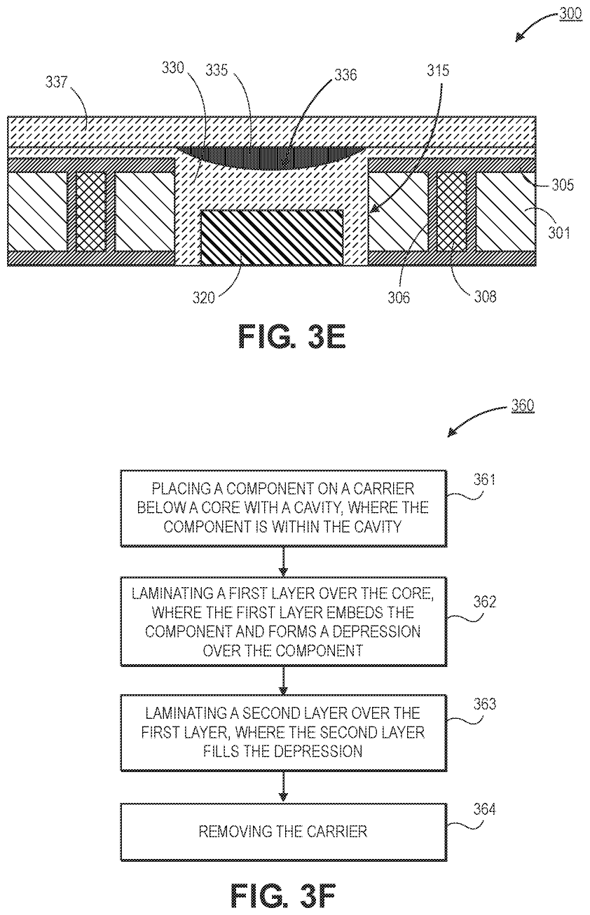

Referring now to FIGS. 3A-3E, a series of cross-sectional illustrations depicting a process for forming a portion of a package substrate 300 with an alternative two layer approach is shown, in accordance with an embodiment.

Referring now to FIG. 3A, a cross-sectional illustration of a portion of a package substrate 300 is shown, in accordance with an embodiment. The package substrate 300 comprises a core 301. The core 301 may be similar to any of the cores described in greater detail herein. Cladding 305 may be provided over and/or under the core 301, and vias 306 may pass through the core 301. The vias 306 may include an electrically insulating plug 308 in some embodiments. In an embodiment, a cavity 315 may pass at least partially through a thickness of the core 301. A temporary carrier 310 may be provided below the core 301 and span across the cavity 315.

In an embodiment, a component 320 may be placed in the cavity 315. The component 315 may have a thickness that is less than a thickness of the core 301. The component 320 may be a passive component that comprises one or more of a capacitor, an inductor, a resistor or the like. In one embodiment, the component is a DTC. The component 320 may be similar to any of the components described in greater detail herein.

In an embodiment, a first film is provided over the core 301. The first film comprises a first layer 330. The first layer 330 may comprise a polymer, an epoxy, an epoxy mold compound, a MUF, an organic dielectric, a composite material, or the like. In an embodiment, the first layer 330 may have a substantially uniform thickness across a width of the first layer 330.

Referring now to FIG. 3B, a cross-sectional illustration of a portion of a substrate 300 at a subsequent stage of assembly is shown, in accordance with an embodiment. As shown, the first layer 330 has been applied to the core 301. The application process may include lamination, molding, pressing, or the like. The first layer 330 partially fills the cavity 315. For example, the first layer 330 may surround the component 320. That is, the first layer 330 may cover sidewalls and a top surface of the component 320. The first layer 330 may also be provided over a top surface of the core 301. In some embodiments, the cladding 305 may separate the first layer 330 from the core 301.

In an embodiment, the first layer 330 may not entirely fill the cavity 315. For example, a depression 332, dent, or other defect may be provided along a top surface of the first layer. As shown, the depression 332 may be a curved surface that is aligned with the cavity 315. For example, a centerline of the cavity 315 may be substantially aligned with a centerline of the depression 332. In some embodiments, the lowest surface of the depression 332 may be inside the cavity 315. That is, the bottom of the depression 332 may be lower than a top surface of the core 301. Though, in other embodiments, the bottom of the depression 332 may be above the top surface of the core 301. The depression 332 may curve away from the component 320. For example, a first line (orthogonal from the surface of the component 320) that starts at a center of the top surface of the component 320 and continues to the depression 332 is shorter than a second line (orthogonal from the surface of the component 320) that starts at an edge of the top surface of the component 320 and continues to the depression 332.

Referring now to FIG. 3C, a cross-sectional illustration of a portion of the package substrate 300 at a subsequent stage of assembly is shown, in accordance with an embodiment. As shown, a second film is positioned over the core 301. The second film may comprise a second layer 335 and a third layer 337. In an embodiment, the second layer 335 is a different material than the first layer 330. For example, the second layer 335 has a higher flowability than the first layer 330. The first layer 330 may have a first viscosity, and the second layer 335 may have a second viscosity that is lower than the first layer 330. As such, the application of force to the second film (e.g., during a lamination process) allows for the second layer 335 to deform and “flow” better than the first layer 330. The third layer 337 may be provided over the second layer 335. The third layer 337 may be a material similar to the first layer 330. Though, the third layer 337 may also be different than the first layer 330 in some embodiments. In an embodiment, the second layer 335 may comprise a polymer, an epoxy, an epoxy mold compound, a MUF, an organic dielectric, a composite material or the like. The second layer 335 may also comprise micro or nano-sized inorganic particulate fillers, fibers, or a mixture of fibers and particulate fillers, similar to the first layer 330 or the third layer 337.

The second layer 335 may be positioned so that the second layer 335 is aligned over the depression 332. The second layer 335 may have a semi-elliptical profile. Though, a rectangular profile or any other profile may be used. A width of the second layer 335 may be similar to a width of the cavity 315 or a width of the depression 332.

Referring now to FIG. 3D, a cross-sectional illustration of a portion of the package substrate 300 at a subsequent stage of assembly is shown, in accordance with an embodiment. As shown, the second film has been laminated or otherwise applied onto the first layer 330. The second layer 335 may fill the depression 332. The third layer 337 may also compress down in order to form a substantially planar top surface. The second layer 335 may also have a substantially planar top surface in some embodiments.

In an embodiment, the second layer 335 conforms to the depression 332. As such, an interface 336 between the first layer 330 and the second layer 335 is formed. The interface 336 may have a non-linear profile. For example, in FIG. 3D the interface 336 is curved away from the component 320, similar to the curvature of the depression 332. In some embodiments, the second layer 335 may be within the cavity 315. In other embodiments, the second layer 335 may be above the cavity 315, but within a footprint of the cavity 315. A midpoint of the interface 336 may be substantially aligned with a centerline of the cavity 315.

Referring now to FIG. 3E, a cross-sectional illustration of a portion of the package substrate 300 at a subsequent stage of manufacture is shown, in accordance with an embodiment. FIG. 3E shows the removal of the temporary carrier 310. The temporary carrier 310 may be removed with a peeling process, an etching process, a delamination, or the like. As shown, a bottom surface of the component 320 may be substantially coplanar with a bottom surface of the cladding 305. If there is no cladding 305 on the core 301, then the bottom surface of the component 320 may be substantially coplanar with a bottom surface of the core 301. As used herein, “substantially coplanar” may refer to two surfaces that are within approximately 10 μm of being coplanar with each other.

Referring now to FIG. 3F, a process flow diagram of a process 360 for embedding a component in a cavity within a core is shown, in accordance with an embodiment. In an embodiment, the process 360 may begin with operation 361, which comprises placing a component on a carrier below a core within a cavity. In an embodiment, the component is within the cavity. The operation 361 may be similar to the structure and process described and illustrated with respect to FIG. 3A.

In an embodiment, the process 360 may continue with operation 362, which comprises laminating a first layer over the core. In an embodiment, the first layer embeds the component and forms a depression over the component. The operation 362 may be similar to the structure and process described and illustrated with respect to FIG. 3B.

In an embodiment, the process 360 may continue with operation 363, which comprises laminating a second layer over the first layer. In an embodiment, the second layer fills the depression. The operation 363 may be similar to the structure and process described and illustrated with respect to FIG. 3C and/or FIG. 3D.

In an embodiment, the process 360 may continue with operation 364, which comprises removing the carrier. The operation 364 may be similar to the structure and process described and illustrated with respect to FIG. 3E.

As can be appreciated from embodiments described herein, the application of a multi-layer embedding process benefits from proper alignment. Particularly, aligning the film or films with the underlying core allows for the second layer to be accurately placed in order to improve the complete filling of the cavity through the core. Accordingly, embodiments disclosed herein may include alignment features.

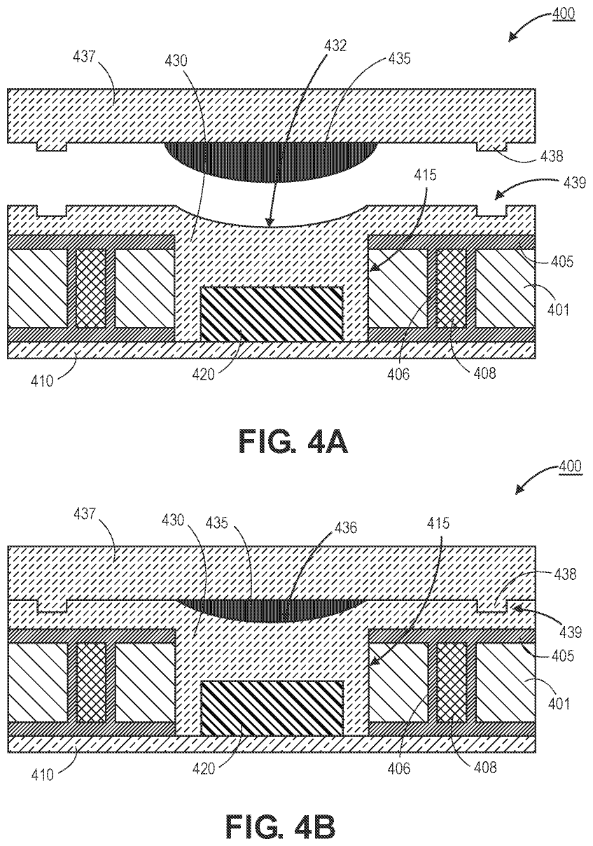

Referring now to FIGS. 4A and 4B, an alignment feature in the first layer 430 and the third layer 437 interlock in order to properly place the second layer 435.

Referring now to FIG. 4A, a cross-sectional illustration of a portion of a package substrate 400 is shown, in accordance with an embodiment. The package substrate 400 may comprise a core 401 that may be similar to any of the cores described in greater detail herein. Vias 406 (with or without plugs 408) may be provided through the core 401, and claddings 405 may be provided over and/or under the core 401. A cavity 415 may be provided at least partially through a thickness of the core 401. A temporary carrier 410 may be provided across the bottom of the cavity 415.

In an embodiment, a component 420 may be placed in the cavity 415 on the temporary carrier 410. The component 420 may be a passive component. The component 420 may be similar to any of the components described in greater detail herein. In an embodiment, a thickness of the component 420 may be less than a thickness of the core 401.

In an embodiment, a first layer 430 may be provided over the core 401 and into the cavity 415. The first layer 430 may at least partially fill the cavity 415 in some embodiments. Additionally, a depression 432 may be provided on the top surface of the first layer 430. The depression 432 may be a curved surface that is centered with the cavity 415. In an embodiment, the first layer 430 may also comprise first alignment features 439. The first alignment features 439 may be trenches or cavities that are formed (e.g., using laser machining, grinding, or any other suitable manufacturing process) into the top surface of the first layer 430.

In an embodiment, a second layer 435 and a third layer 437 are provided over the core 401. The third layer 437 may have second alignment features 438. The second alignment features 438 may be protrusions that interlock with the first alignment features 439. For example, the protrusions may have a rectangular shaped cross-section. In an embodiment, the second layer 435 is centered over the depression 432. The centering of the second layer 435 is enabled through the use of the first alignment features 439 and the second alignment features 438.

Referring now to FIG. 4B, a cross-sectional illustration of a portion of the package substrate 400 after the first layer 430 and the third layer 437 are pressed together is shown, in accordance with an embodiment. As shown, the first alignment features 439 are filled by the second interlocking alignment features 438. This properly centers the second layer 435 with the depression 432. Similar to embodiments described in greater detail above, the first layer 430 and the second layer 435 meet at a non-linear interface 436.

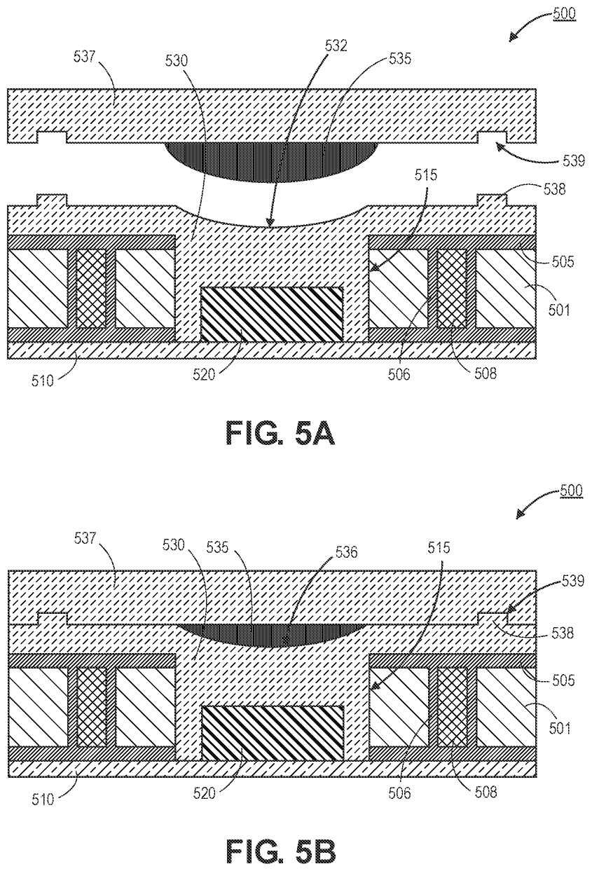

Referring now to FIGS. 5A and 5B, a cross-sectional illustration of a portion of a package substrate 500 is shown, in accordance with an additional embodiment. The package substrate 500 may be similar to the package substrate 400 except that the alignment features are reversed.

Referring now to FIG. 5A, a cross-sectional illustration of a portion of a package substrate 500 is shown, in accordance with an embodiment. The package substrate 500 may comprise a core 501 that may be similar to any of the cores described in greater detail herein. Vias 506 (with or without plugs 508) may be provided through the core 501, and claddings 505 may be provided over and/or under the core 501. A cavity 515 may be provided at least partially through a thickness of the core 501. A temporary carrier 510 may be provided across the bottom of the cavity 515.

In an embodiment, a component 520 may be placed in the cavity 515 on the temporary carrier 510. The component 520 may be a passive component. The component 520 may be similar to any of the components described in greater detail herein. In an embodiment, a thickness of the component 520 may be less than a thickness of the core 501.

In an embodiment, a first layer 530 may be provided over the core 501 and into the cavity 515. The first layer 530 may at least partially fill the cavity 515 in some embodiments. Additionally, a depression 532 may be provided on the top surface of the first layer 530. The depression 532 may be a curved surface that is centered with the cavity. In an embodiment, the first layer 530 may also comprise first alignment features 538. The first alignment features 538 may be protrusions that are extend up from the top surface of the first layer 530.

In an embodiment, a second layer 535 and a third layer 537 are provided over the core 501. The third layer 537 may have second alignment features 539. The second alignment features 539 may be trenches or cavities that interlock with the first alignment features 538. In an embodiment, the second layer 535 is centered over the depression 532. The centering of the second layer 535 is enabled through the use of the first alignment features 538 and the second alignment features 539.

Referring now to FIG. 5B, a cross-sectional illustration of a portion of the package substrate 500 after the first layer 530 and the third layer 537 are pressed together is shown, in accordance with an embodiment. As shown, the first alignment features 538 fill the second alignment features 539. This properly centers the second layer 535 with the depression 532. Similar to embodiments described in greater detail above, the first layer 530 and the second layer 535 meet at a non-linear interface 536.

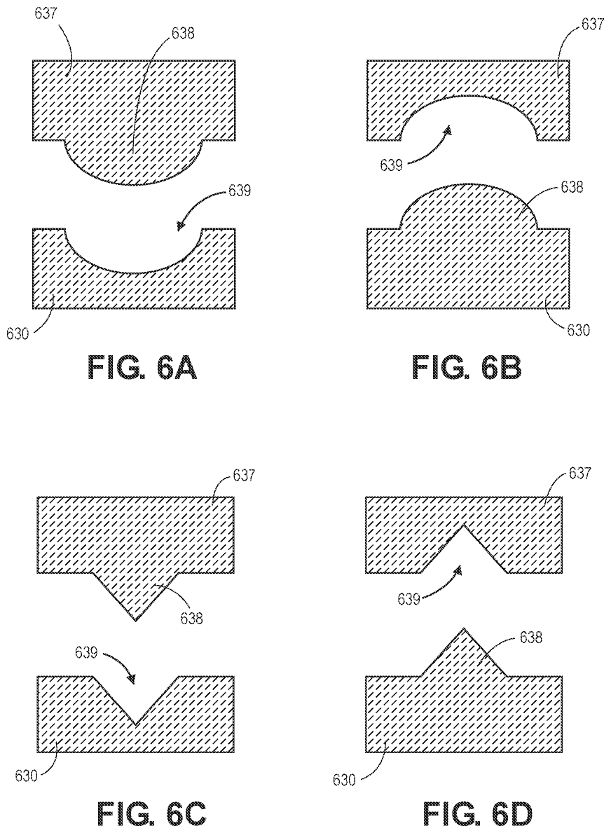

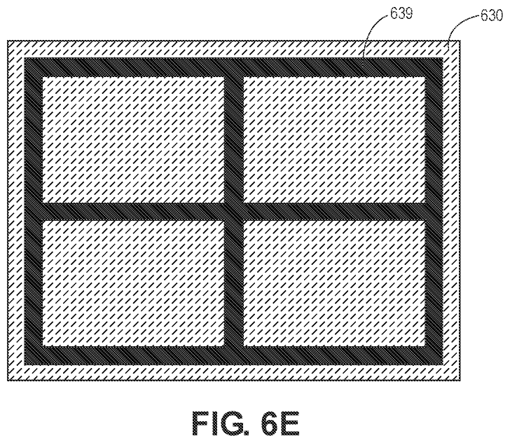

In FIGS. 4A-5B, rectangular alignment features are shown as one example. However, it is to be appreciated that alignment features may have any suitable cross-section. Additional examples are shown in FIGS. 6A-6D.

Referring now to FIG. 6A, a cross-sectional illustration of alignment features in a first layer 630 and a third layer 637 is shown, in accordance with an embodiment. The first alignment feature 639 in the first layer 630 may be a curved trench, and the second alignment feature 638 in the third layer 637 may be a semi-elliptical protrusion. In FIG. 6B, the alignment features are switched so that the first alignment feature 639 is a trench in the third layer 637, and the second alignment feature 638 is a semi-elliptical protrusion out from the first layer 630. In FIG. 6C, the first alignment feature 639 is a triangular trench in the first layer 630, and the second alignment feature 638 is a triangular protrusion out from the third layer 637. In FIG. 6D, the first alignment feature 639 is a triangular trench into the third layer 637, and the second alignment feature 638 is a triangular protrusion out from the first layer 630. While several examples of interlocking features are shown, it is to be appreciated that any interlocking architecture (or combination thereof) may be used in some embodiments.

Referring now to FIG. 6E, a plan view illustration of a first layer 630 is shown, in accordance with an embodiment. The first layer 630 may be provided over a plurality of cores (not visible) that are provided as a single larger substrate (e.g., a panel or quarter-panel). As shown, an alignment feature 639 may be provided on the first layer 630. For example, the alignment feature 639 may be a ring around a perimeter of the first layer 630. Lines of the alignment feature 639 may also be provided across the first layer 630. For example, the alignment feature 639 may be at the boundaries between quarter-panels or at the boundaries between units within a quarter panel in some embodiments. The alignment feature 639 may be a trench or a protrusion with any suitable cross-section, such as those described in greater detail herein.

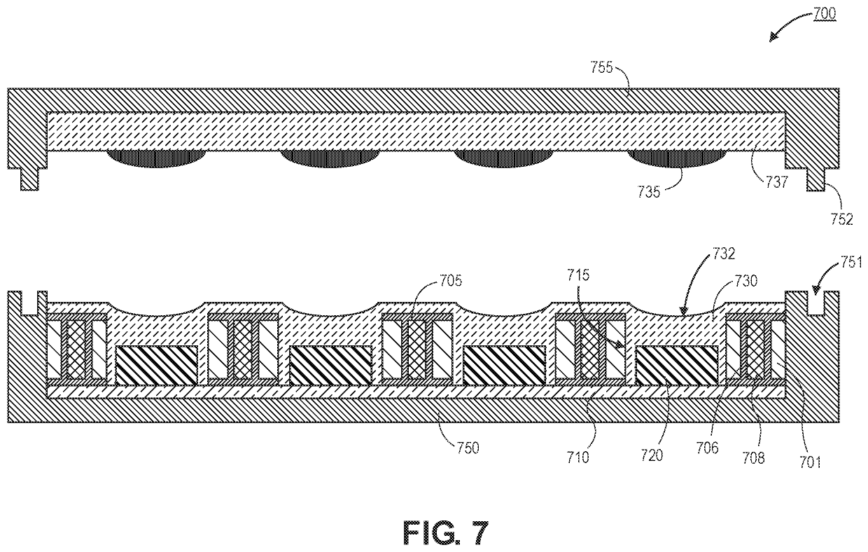

Referring now to FIG. 7, a cross-sectional illustration of a portion of a package substrate 700 is shown, in accordance with an additional embodiment. The package substrate 700 may comprise a core 701 that may be similar to any of the cores described in greater detail herein. Vias 706 (with or without plugs 708) may be provided through the core 701, and claddings 705 may be provided over and/or under the core 701. A cavity 715 may be provided at least partially through a thickness of the core 701. A temporary carrier 710 may be provided across the bottom of the cavity 715.

In an embodiment, a component 720 may be placed in the cavity 715 on the temporary carrier 710. The component 720 may be a passive component. The component 720 may be similar to any of the components described in greater detail herein. In an embodiment, a thickness of the component 720 may be less than a thickness of the core 701.

In an embodiment, a first layer 730 may be provided over the core 701 and into the cavity 715. The first layer 730 may at least partially fill the cavity 715 in some embodiments. Additionally, a depression 732 may be provided on the top surface of the first layer 730. The depression 732 may be a curved surface that is centered with the cavity.

In an embodiment, a second layer 735 and a third layer 737 are provided over the core 701. In an embodiment, the second layer 735 is centered over the depression 732. The centering of the second layer 735 is enabled through the use of alignment features. More particularly, alignment frames 750 and 755 may be used. The first frame 750 may hold the core 701, and the second frame 755 may hold the third layer 737. The first frame 750 may have a first alignment feature 751, and the second frame 755 may have a second alignment feature 752 that is configured to interlock with the first alignment feature 751. In FIG. 7, the first alignment feature 751 is a trench and the second alignment feature 752 is a protrusion. Though, the alignment features may be switched, or each frame 750/755 may have a mix of protrusions and trenches. The alignment features 751 and 752 may include cross-sections of any suitable interlocking shapes.

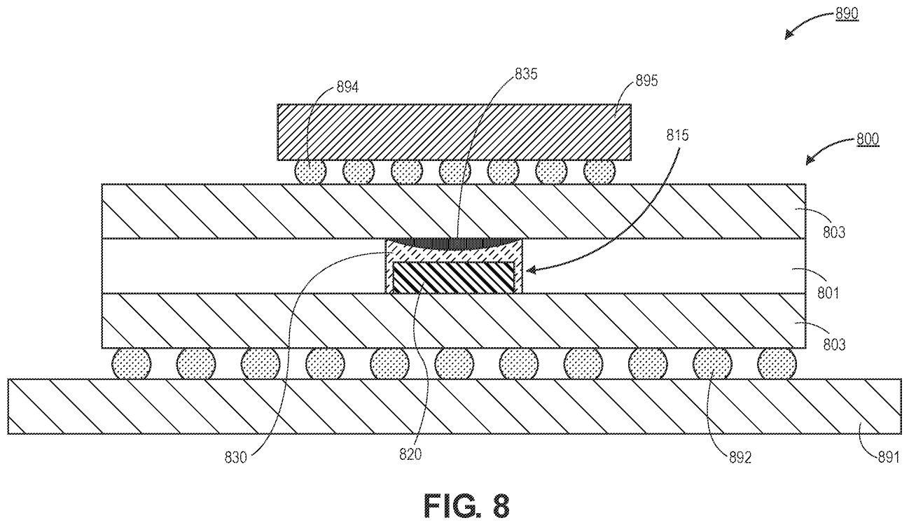

Referring now to FIG. 8, a cross-sectional illustration of an electronic system 890 is shown, in accordance with an embodiment. The electronic system 890 may comprise a board 891, such as a printed circuit board (PCB), a motherboard, or the like. In an embodiment, a package substrate 800 is coupled to the board 891 by interconnects 892. The interconnects 892 may comprise any second level interconnect (SLI) architecture, such as solder balls, sockets, pins, or the like.

In an embodiment, the package substrate 800 may comprise a core 801 with buildup layers 803 over and/or under the core. The core 801 may be substantially similar to any of the cores described in greater detail herein. In an embodiment, the core 801 is a glass core or an organic core. The core 801 may comprise a cavity 815. A component 820 may be placed in the cavity 815. The component 820 may be a passive component, such as any passive component describe in greater detail herein. In an embodiment, the remainder of the cavity 815 may be filled with a two-layer fill structure. A first layer 830 may embed the component 820, and a second layer 835 may fill the remainder of the cavity 815. The second layer 835 and the first layer 830 may have a curved interface. While one fill architecture is shown in FIG. 8, it is to be appreciated that any multi-layer filling solution similar to architectures described in greater detail herein may be used.

In an embodiment, one or more dies 895 may be coupled to the package substrate 800 by interconnects 894. The interconnects 894 may be any suitable first level interconnect (FLI) architecture, such as solder balls, copper bumps, hybrid bonding interfaces, or the like. In an embodiment, the die 895 may be any suitable type of die. For example, the die 895 may comprise a central processing unit (CPU), a graphics processing unit (GPU), an XPU, a communications die, a memory die, an application specific integrated circuit (ASIC), a field-programmable gate array (FPGA), or the like.

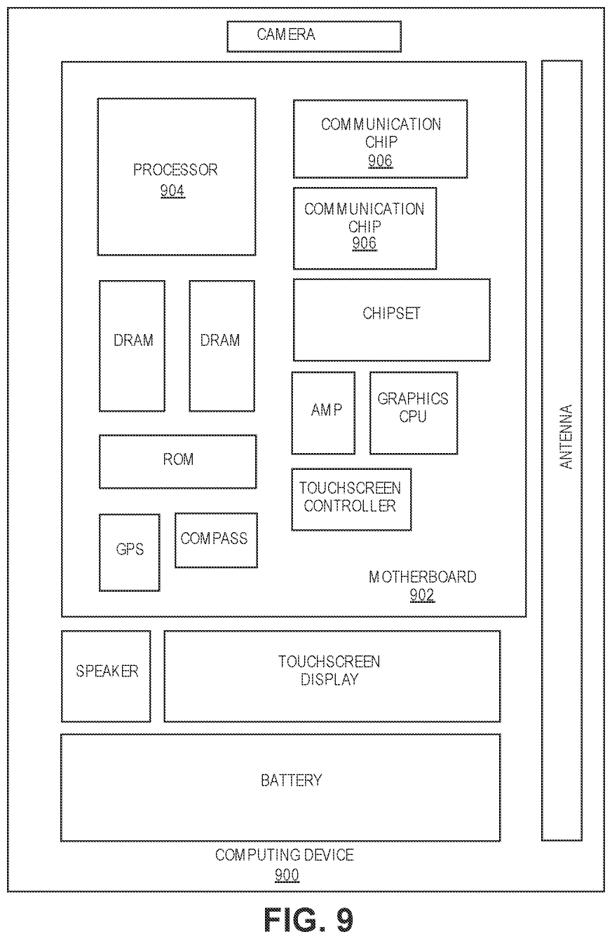

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that includes a core with a cavity that is filled by a component and a multi-layer fill, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that includes a core with a cavity that is filled by a component and a multi-layer fill, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate; a cavity through a thickness of the substrate; a component in the cavity; a first layer in the cavity, wherein the first layer is a dielectric material; and a second layer in the cavity, wherein the second layer is a dielectric material, wherein the first layer is a different material than the second layer.

Example 2: the apparatus of Example 1, wherein the component is at least partially embedded in the first layer.

Example 3: the apparatus of Example 1 or Example 2, wherein the first layer and the second layer meet at a curved interface.

Example 4: the apparatus of Example 3, wherein a midpoint of the curved interface is aligned with a centerline of the cavity.

Example 5: the apparatus of Examples 1-4, wherein the first layer has a first viscosity and the second layer has a second viscosity that is higher than the first viscosity.

Example 6: the apparatus of Examples 1-5, wherein the substrate has a first thickness and the component has a second thickness that is smaller than the first thickness.

Example 7: the apparatus of Example 6, wherein a surface of the substrate is substantially coplanar with a surface of the component.

Example 8: the apparatus of Examples 1-7, wherein the component comprises one or more of a capacitor, an inductor, or a resistor.

Example 9: the apparatus of Examples 1-8, wherein the substrate is a solid glass layer with a rectangular prism form factor.

Example 10: the apparatus of Examples 1-9, wherein the first layer covers a top surface of the substrate.

Example 11: an apparatus, comprising: a substrate; a cavity into a surface of the substrate; a component in the cavity, wherein the component has a first surface, a second surface opposite from the first surface, and a sidewall surface connecting the first surface to the second surface; a first layer that contacts the sidewall surface and the second surface of the component; and a second layer on the first layer.

Example 12: the apparatus of Example 11, wherein the first layer and the second layer are both at least partially within the cavity.

Example 13: the apparatus of Example 11 or Example 12, wherein an interface between the first layer and the second layer is curved.

Example 14: the apparatus of Examples 11-13, wherein the first layer directly contacts the substrate, and wherein the second layer is spaced apart from the substrate by the first layer.

Example 15: the apparatus of Examples 11-14, wherein the component is a passive electrical device.

Example 16: the apparatus of Examples 11-15, wherein the cavity passes through an entire thickness of the substrate.

Example 17: an apparatus, comprising: a board; a package substrate coupled to the board, wherein the package substrate comprises: a core with an embedded passive component, wherein the passive component is in a cavity that is filled with a first layer and a second layer that is different than the first layer; and a die coupled to the package substrate.

Example 18: the apparatus of Example 17, wherein the core is a solid glass material that has a thickness that is at least 50 μm, and wherein the core is thicker than the passive component.

Example 19: the apparatus of Example 17 or Example 18, wherein an interface between the first layer and the second layer is a curved line.

Example 20: the apparatus of Examples 17-19, wherein the apparatus is part of a personal computer, a server, a mobile device, a tablet, or an automobile.

What is claimed is:

1. An apparatus, comprising:
a substrate;
a cavity through a thickness of the substrate;
a component in the cavity;
a first layer in the cavity, wherein the first layer is a dielectric material; and
a second layer in the cavity, wherein the second layer is a dielectric material, wherein the first layer is a different material than the second layer.

2. The apparatus of claim 1, wherein the component is at least partially embedded in the first layer.

3. The apparatus of claim 1, wherein the first layer and the second layer meet at a curved interface.

4. The apparatus of claim 3, wherein a midpoint of the curved interface is aligned with a centerline of the cavity.

5. The apparatus of claim 1, wherein the first layer has a first viscosity and the second layer has a second viscosity that is higher than the first viscosity.

6. The apparatus of claim 1, wherein the substrate has a first thickness and the component has a second thickness that is smaller than the first thickness.

7. The apparatus of claim 6, wherein a surface of the substrate is substantially coplanar with a surface of the component.

8. The apparatus of claim 1, wherein the component comprises one or more of a capacitor, an inductor, or a resistor.

9. The apparatus of claim 1, wherein the substrate is a solid glass layer with a rectangular prism form factor.

10. The apparatus of claim 1, wherein the first layer covers a top surface of the substrate.

11. An apparatus, comprising:
a substrate;
a cavity into a surface of the substrate;
a component in the cavity, wherein the component has a first surface, a second surface opposite from the first surface, and a sidewall surface connecting the first surface to the second surface;
a first layer that contacts the sidewall surface and the second surface of the component; and
a second layer on the first layer.

12. The apparatus of claim 11, wherein the first layer and the second layer are both at least partially within the cavity.

13. The apparatus of claim 11, wherein an interface between the first layer and the second layer is curved.

14. The apparatus of claim 11, wherein the first layer directly contacts the substrate, and wherein the second layer is spaced apart from the substrate by the first layer.

15. The apparatus of claim 11, wherein the component is a passive electrical device.

16. The apparatus of claim 11, wherein the cavity passes through an entire thickness of the substrate.

17. An apparatus, comprising:
a board;
a package substrate coupled to the board, wherein the package substrate comprises:
a core with an embedded passive component, wherein the passive component is in a cavity that is filled with a first layer and a second layer that is different than the first layer; and
a die coupled to the package substrate.

18. The apparatus of claim 17, wherein the core is a solid glass material that has a thickness that is at least 50 μm, and wherein the core is thicker than the passive component.

19. The apparatus of claim 17, wherein an interface between the first layer and the second layer is a curved line.

20. The apparatus of claim 17, wherein the apparatus is part of a personal computer, a server, a mobile device, a tablet, or an automobile.
